(19) United States
(12) Patent Application Publication
(10) Pub. No.: US 2026/0070285 A1
(43) Pub. Date: Mar. 12, 2026

(54) PROCESS AND DESIGN FOR ADDITIVE MANUFACTURE OF PINCERS AND NIPPERS

(71) Applicant: David Thomas Jones, Bechtelsville, PA (US)

(72) Inventor: David Thomas Jones, Bechtelsville, PA (US)

(21) Appl. No.: 18/828,350

(22) Filed: Sep. 9, 2024

(51) Int. Cl. B29C 64/386; B33Y 50/00; B33Y 80/00; G06F 30/23

(52) U.S. Cl. CPC B29C 64/386; B33Y 50/00; G06F 30/23; B33Y 80/00

(57) ABSTRACT

Described is a design and process for additive manufacture of pincers or nippers. 3D printing allows the rapid and efficient manufacture of individually designed tools for increased customer satisfaction and reduction of waste and inventory. This invention overcomes problems with existing manufacturing practices such as waste, lack of variability and user ergonomics. The problem to be addressed is that these tools can be subjected to very high flexural pressures and the design must be unique. For example, even steel nipper handles can bend under such pressures, so polymer tools must be specially designed and not just copied from the existing design and technology. For the end user, the design and manufacture of the nipper handles can be configured to the users'specifications and produced individually and cost-effectively by innovative additive manufacturing techniques. The materials used for the handles are of a specially configured, individually 3D printed polymer material which can be various sizes, shapes and a variety of colors, as well as contours or individualized finger grooves for comfort and stability. For the manufacturer, custom pincers or nippers can be individually produced to a user's preferences with small changes in programming, inexpensive materials and no waste. The configuration of the handles can be a larger, lighter, and more comfortable in shape and size. Infill can be easily designed to reinforce high stress areas while reducing weight which monolithic manufacturing cannot do. Because of the increased flexural strength required for pincers, certain new and innovative designs are introduced. In order to utilize the most cost-effective materials, certain innovative configuration parameters are described.

### CROSS-REFERENCE TO RELATED APPLICATIONS

Not applicable.

### STATEMENT REGARDING FEDERALLY SPONSORED RESEARCH OR DEVELOPMENT

Not applicable.

### REFERENCE TO SEQUENCE LISTING, A TABLE OR A COMPUTER PROGRAM

Not applicable.

### BACKGROUND OF THE INVENTION

### 1. Field of the Invention

The present invention relates to hand tools, and specifically to a method for designing hand tools for additive manufacturing processes.

### 2. The Description of Prior Art

Pincers are a hand tool used in many situations where a mechanical advantage is required to pinch, cut or pull an object. The manufacture of opposing blade pincers has been done at least since Greco-Roman times.

Spring-back, or tweezer-like, tongs were the model used by the early smiths. These were essentially thin steel with a bend in the middle hammered one at a time on an anvil. The change to the mechanically more effective hinged tongs was slow, and it was not until 500 BCE that they became common in the Greek blacksmith's kit. Pivoted tongs, with short jaws and a long handle, have quite a mechanical advantage over tweezer-like tongs. A pair of 51-cm (20-inch) pivoted tongs is capable of exerting a gripping force of nearly 135 kg (300 pounds) with only a 18-kg (40-pound) squeeze from the operator's hand. These more complicated tools were also hammered one at a time on an anvil. Mass production comprised more smiths and more anvils.

Small tongs, often called pliers or forceps, were particularly valuable to the early craftsperson. who put them to many and varied uses. The Romans sharpened the jaws of tongs to create cutters and pincers. The pincers were useful for pulling bent nails because of the leverage they were capable of exerting. Although they were originally a carpenter's tool, pincers became a principal tool of the farrier because old nails had to be pulled from horses'hooves before new shoes could be fitted and nailed on. (Encyclopedia Britannica)

The earliest patent I found that improved on the ancient design was awarded to Abraham Baker on Aug. 7, 1860 (U.S. Pat. No. 29,543). In this disclosure normally biased cross cutting handles have one blade sharpened while the other acts an anvil. A set screw limits closure travel. An award for “Hoof Nippers” was given to Henry B. Ward on Dec. 18, 1906 U.S. Pat. No. 838,597. This disclosed one stationary end cutter handle and one end cutter moveable handle. On Oct. 26, 1909 U.S. Pat. No. 938,376, “Nippers” was awarded to Martin Friday for adjustable jaws on a typical end cutter nippers. Titled “Nippers and Pincers”, U.S. Pat. No. 951,076 was awarded to Eli Jones on March 1, 1910. These end cutting nippers had a complex design of lap handles for additional leverage. A provisional patent application by David T. Jones (myself) gave a rudimentary description of this future application, but very inadequate. On Jul. 12, 1938 a German U.S. Pat. No. 2,123,357 was awarded to C. G Grah, et. al. for a cross-cut nipper design with a flat spring, entitled “Nippers for Skin and Fingernails”. With the exception of the last patent, none of the improvements disclosed and awarded are currently commercially available. Rather, the simple medieval design is by far the one being produced, sold and used. These are typically mass produced by forging and are biased handles where the cutting edges are parent metal and the pivot is a steel rivet.

As the Prior Art shows, there have been many improvements patented on the ancient design of pincers. Nearly none of them have actually been put into production and the most commonly used design currently is still the original which dates back to the Greek and Roman design, perhaps because it is the simplest and easiest to manufacture. From a manufacturing point of view the current design uses minimal steel material for cost effectiveness, designed for minimal strength, but the narrowness of the handles is not comfortable nor lightweight. Craftsmen continue to struggle with these tools, as I well know.

Subtractive manufacturing involves removing material from a stock piece to create the desired part. It is wasteful because of the scrap and operations like forging and casting generally require additional secondary operations like grinding and polishing, to make a finished product, and also involve scrap. Additive manufacturing, as opposed to subtractive practices such as machining, has been in practice in various forms for fewer years. Electric welding has been used to build up metals and polymers have been used to manufacture some light-use products. 3D Printing with polymer filament is a relatively new technology that has only been patented and in use for the past 30 years.

The limitation has been with 3D printing is that it has typically been only used to manufacture products not exposed to stress forces and those limitations accepted as such. Mostly used for decorative items or prototype displays to demonstrate size and fit; 3D printing materials, filaments, are only now created with stronger chemistry. Because pincers of all types are subjected to very strong torsion forces, a new design is required to be able to produce them to be sufficiently functional.

3D printing enables previously impossible products to be made because it creates from the inside out, whereas subtractive machining creates from the outside in. Plus, recent innovations in 3D printing allows interior features and modifications such as stress-resistant lattice infill which were impossible only a few years ago. This invention takes advantage of, and expands on, these most recent opportunities.

This much anticipated product patent would have been impossible to apply for before 2021, and certain procedures, such as manipulating CAD model internal lattice infill using stress analysis and simulation have only been possible in the last few years.

Having spent my entire career, over 50 years, in designing and manufacturing a variety of products, efficiency has become a way of life for me. I have designed and manufactured products from machined metal objects to robotics, so the invention of additive manufacturing, particularly 3D printing was especially exciting. Having also spent 32 years using commercially available medieval origin tools to trim horse hooves, I have an appreciation for the need for urgent improvements to those tools.

As an example, tools traditionally used for trimming of hooved animals (ungulates), commonly referred to as nippers, maintain the same design from the middle-ages whereby the blade sections are of the same continuous monolithic materials as the handles. The handles are typically fastened at the pivot point by a non-adjustable rivet. To be price competitive, these tools are also typically made in large quantities by forging, with additional secondary operations such as machining and heat treating being required as well as grinding and polishing for user acceptance. A mold for forging those can easily cost more than $40,000 and a forging press can be over $100,000 before the first part is made and large lots must then be produced to be cost effective. Then, the customer can buy only the style and size available. From a manufacturing point of view the current design uses minimal steel material for cost effectiveness, designed for minimal strength, but the narrowness of the handles is not comfortable nor lightweight. For example, steel handles are typically 12 mm wide and a nipper set can weigh 634 grams, whereas polymer handles can be 22 mm wide and a comparable nipper set can weigh 109 grams. less than one third the weight and much more ergonomic. Because the blade sections are the same low hardness as the monolithic parent metal and one continuous piece as the handles, they dull easily and must be resharpened, often requiring disassembly, by one skilled in the craft, typically not the user. Alternatively, polymer pincers can be equipped with replaceable blades of much more durable material. Also, this steel tool design is heavy and difficult to use for the 85% of the horse owners in the United States who are women. Because more women are learning the trade of hoof trimming, they bring new expectations to the market for lightweight, easier to use pincers and even for personalized choices such as size, contours and color. In response to these issues and shortcomings what is desired from a users'point of view are pincers that are lightweight yet sharp, strong and durable enough for the task with replaceable blades. What is desired from a manufacturing viewpoint is a pincer design that can be individually and cost-effectively customized to each individual customer's preferences, saving on inventory and more appealing to users.

The actual additive manufacturing, 3D printing, is fairly recent. The first prototype process started in 1987 was Stereolithography, which used ultraviolet light to cure photopolymers. But it was not until 2009 when the first 3D printers we are familiar with appeared, called Fused Deposition Modeling technology. FDM is the simplest 3D printing technology; it involves heating up a polymer filament until it melts, and then extruding it out layer-by-layer. This technology was still not strong enough to manufacture polymer pincers that would withstand the force required to trim equine hooves, until the present invention.

### BRIEF SUMMARY OF THE DISCLOSURE

The present invention addresses problems of both manufacturer and consumer with currently available pincers and nippers. Current profitable manufacture of pincers and nippers typically involves forging carbon-based metals using a mold and mass production of multiple units and there are typically waste and additional operations necessary for customer acceptance as well as the high cost of making a forging mold. For customers, this limits the available options. This disclosure addresses the problems involved with additive manufacture of pincers and nippers. Because pincers can be subjected to unusual amounts of flexural forces in typical uses, they have historically been fabricated with high strength materials, such as iron and steel. Even then the handles of these pincers are demonstrated to experience bending moments. Also, to efficiently manufacture metal pincers the cutting edges are typically made along with the handles in a monolithic structure of softer metal and the cutting edges wear faster and need to be rebuilt by someone skilled in the craft for as much as $200 each. This forces the customer to be without use of the tool while it is being repaired. Although polymers have come a long way in increased strength and durability, they are still not equivalent to iron or steel. Carbon or fiberglass filled polymers have advanced properties and are being used in additive manufacturing such as 3D Printing. The main advantage in using polymers to manufacture pincers is that they can be efficiently manufactured one at a time and also that cross-sectional size of the handles can be increased and still be lighter in weight and more comfortable than iron or steel. A specially designed lattice of infill can be formed in the interior of the handles which cannot be done with subtractive manufacturing. This adds strength and rigidity to the products while reducing weight as a properly designed lattice can be stronger than 100% fill. Additive manufacture allows cost effective and customized individual products to be made simply by changing programs. Options such as size, length, color and handling features such as contours and finger grooves add to customer satisfaction and replaceable hardened blades can easily be changed by the user. Additive manufacture of pincers and nippers are more profitable for the manufacturer and more satisfactory for the consumer.

This disclosure describes designs for increased performance of the products and improved configurations for additive manufacturing. For the end user, additive manufacturing, such as 3-D printing offers a wide range of possibilities to customize tools that are more pleasing to each individual end users. Ergonomic ease of use of pincers are the most important consumer desire but various sizes and even a variety of color preferences and handle configurations such as contours or finger grooves can now be made available to consumers on an individual basis. For the manufacturer, additive manufacturing offers reduction of waste and the ability to use best manufacturing practices such as Make To Order (MTO) and Just in Time (JIT) Manufacturing for reduced inventory. The present invention describes novel advances in additive manufacturing materials, designs and practices that enable manufacturing to the desired and required specifications. When the most currently available cost-effective materials are used, a more robust pattern must be designed, but the additive manufacturing process itself must be configured to add additional infill material in high stress areas while maintaining minimal weight. This technology is still very new and evolving and this novel invention is designed to quickly take advantage of any new developments.

### BRIEF DESCRIPTION OF THE DRAWINGS

Some embodiments of the present invention are illustrated as an example and are not limited by the figures of the accompanying drawings, in which like references may indicate similar elements and in which:

FIG. 1 is a side view of the nipper handle design, one half of a matching set.

FIG. 2 is a cross-sectional view of the perimeters and infill.

FIG. 3 is a cross-section view of a preferred gyroid infill.

### DETAILED DESCRIPTION OF THE INVENTION:

The terminology used herein is for the purpose of describing particular embodiments only and is not intended to be limiting of the invention. As used herein, the term “and/or” includes any and all combinations of one or more of the associated listed items. As used herein, the singular forms “a,” “an,” and “the” are intended to include the plural forms as well as the singular forms, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

Unless otherwise defined, all terms (including technical and scientific terms) used herein have the same meaning as commonly understood by one having ordinary skill in the art to which this invention belongs. It will be further understood that terms, such as those defined in commonly used dictionaries, should be interpreted as having a meaning that is consistent with their meaning in the context of the relevant art and the present disclosure and will not be interpreted in an idealized or overly formal sense unless expressly so defined herein.

In describing the invention, it will be understood that a number of techniques and steps are disclosed. Each of these has individual benefits and each can also be used in conjunction with one or more, or in some cases all, of the other disclosed techniques. Accordingly, for the sake of clarity, this description will refrain from repeating every possible combination of the individual steps in an unnecessary fashion. Nevertheless, the specification and claims should be read with the understanding that such combinations are entirely within the scope of the invention and the claims.

In the following description, for purposes of explanation, numerous specific details are set forth in order to provide a thorough understanding of the present invention. It will be evident, however, to one skilled in the art, that the present invention may be practiced without these specific details.

The present disclosure is to be considered as an exemplification of the invention and is not intended to limit the invention to the specific embodiments illustrated by the figures or description below.

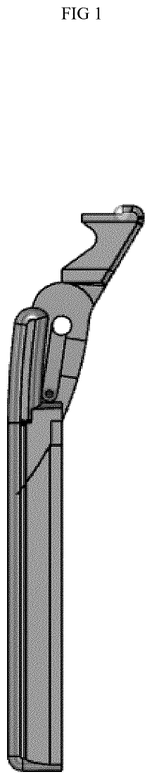

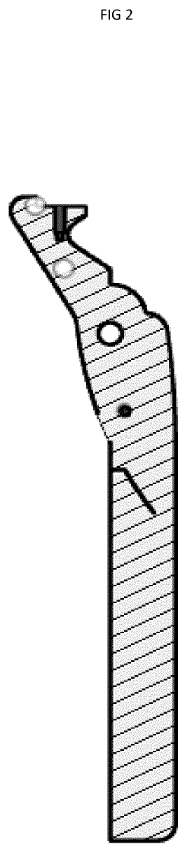

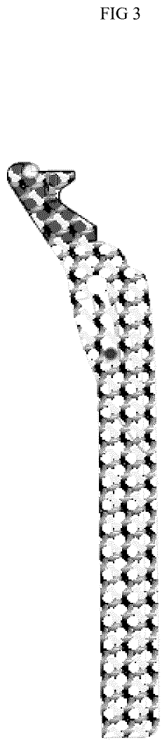

The present invention will now be described by referencing the appended figures representing preferred embodiments. FIG. 1 depicts an example of a model of the desired design showing reinforcements. FIG. 2 depicts a cross-sectional view showing infill locations and robust perimeters. FIG. 3 depicts a cross-sectional view of a preferred gyroid infill pattern. A 3D model may be first drawn using Computer Assisted Design (CAD) software. Research, modeling and testing as well as materials to be used will determine the dimensions of the model taking into consideration the forces involved in the finished product's intended application. Computer Finite Element Analysis (FEA) can be used to determine stress points and recommend number of perimeters and percent and gradient of infill to counter those stress areas. There are a variety of materials of different strengths available. In the preferred embodiment, the material Polylactic Acid (PLA) was designed in due to its adequate strength, ready availability and lower cost. Testing of previous models provided the necessary dimensions to ensure adequate strength. Personal experience and feedback provided the comfort and ease of use features, such as the curved surfaces and width of the hand contact surfaces.

The improved design, besides being much lighter, allowed for wider handles which provide more comfort on the hands. Because the new improved handle design may not be the same material as the blade material, this method of manufacture allowed the use of replaceable blades that may be of much better quality than the traditional method of monolithic manufacture allows. Because the new manufacture allows flexibility of design, the nipper handles may be manufactured to allow for an internal spring that would bias the handles for more control and easier one-handed use. The new design allows for less space between opposing handle distal ends for a narrower closed gap, for efficiency and ease of use for smaller hands. The handles may be customized to the customer's preferred length, which may typically be nine to fifteen inches long.

The handle, FIG. 1, may be designed for efficiency of the additive manufacturing operation. Two identical handles assembled opposingly on a pivot fastener comprise the pincers.

In this present invention, the number of perimeters of the pattern, and top and bottom of the model may be increased as well as the density of the infill. For example, experimentation has shown that the number of perimeters is more important than the percent of infill, resulting in stronger product but with less weight, less material used and faster print speeds. For improved strength, adhesion and speed of printing, either a larger nozzle can be used (for example 0.8 mm rather than the standard 0.4 mm), or the layer height setting can be increased. Infill gradients and density of infill may be increased in flexural stress areas determined using computer simulation. Choice of infill pattern is available, with gyroid being the strongest and most recent. These practices allow a robust product with minimum weight. Because of the principle of additive manufacturing to fabricate one part at a time allows physical stress testing before many are completed, any weaknesses can be easily adjusted for the next part. The polymer materials may be thicker in certain areas to withstand the torque forces typically applied during use. This may be done using Finite Element Analysis when configuring the model to send for 3D printing. This process is an important improvement over the monolithic materials currently manufactured and available which are incapable of innovative design.

The file may be sent to a 3D printer which forms the model using molten extruded polymer material.

Materials used in the present invention may be environmentally friendly Polylactic Acid (PLA), preferred primarily because it is an inexpensive thermoplastic monomer derived from renewable, organic starches; or a more expensive Carbon Fiber Nylon, because of its superior flexural strength. The materials may be extruded using a presently commercially available 3D extrusion printer which applies molten layers of material in a computer designed pattern on its surface table.

A major advantage of 3D printing is that finishing operations such as machining or grinding that required secondary operations in previous manufacturing practices, such as forging or casting, are unnecessary and can just be programmed in to be extruded. This includes recesses, threaded holes, smooth surfaces and burr-free contours.

The 3D manufacturing operation is a one-step process, although “annealing” finished products using a low heat can be an additional operation for added strength, if desired. Reheating the substance to its glass transition temperature or just above, but below its melting temperature (60 to 70 Centigrade for PLA). This temperature is maintained here for a time, about an hour depending on the oven, before slowly allowing it to cool for another hour. This reheating and extended cooling increases strength and redistributes the stresses within the printed part, by increasing the amount of large crystalline structures in the plastic.

FIG. 1 shows the side view of a handle body example. Two identical handles assembled opposingly on a pivot fastener comprise the pincers.

FIG. 2 shows an example of the infill area and perimeters.

FIG. 3 shows an example of a preferred gyroid infill pattern determined through physical stress testing.

The above description is given by way of example and not limitation. Given the above disclosure, one skilled in the art could devise variations that are within the scope and spirit of the invention disclosed herein, including various equipment or various materials. Further, the various features of the embodiments disclosed herein may be used alone, or in varying combinations with each other and are not intended to be limited to the specific combination described herein. Thus, the scope of the claims is not to be limited by the illustrated embodiment.

What is claimed is:

1. A method for improving design for additive manufacturing of pincers, comprising:
Designing pincers that meet both manufacturer and end user requirements to optimize strength and ergonomics and appearance for maximum utilization of cost-effective materials,
Dependent claims:
Claim 1 where; Determining optimum handle dimensions for maximum strength and ergonomic comfort,
Claim 1 where; Determining optimum settings of manufacturing equipment for maximum benefit from cost-effective materials,
Claim 1 where; Computer simulation of optimum infill and perimeters,
Claim 1 where; Design of handle contours for strength and ergonomics,
Claim 1 where; Appropriate materials for user requirements for color or patterns are chosen.

2. A process for improved strength using additive manufacturing to manufacture pincers and nippers from additive materials, comprising:
Analysis and control of parameters in additive manufacturing and determining additive manufacturing equipment settings of additive materials,
Dependent claims:
Claim 2 where; Determine optimum materials and corresponding additive manufacturing settings,
Claim 2 where; Determining most cost-effective materials for production,
Claim 2 where; Determining optimum handle dimensions for maximum strength and ergonomic comfort,
Claim 2 where; Determining optimum settings of printer for maximum benefit from cost-effective materials,
Claim 2 where; Computer simulation of optimum infill and perimeters depending on materials is incorporated using Finite Element Analysis,
